(19) United States
(12) Patent Application Publication
(10) Pub. No.: US 2009/0038831 A1
(43) Pub. Date: Feb. 12, 2009

(54) Printed Circuit Board

(75) Inventors: Shu-Yuan Hsueh, Taipei (TW); Chiu-Chuan Ho, Taipei (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: ASUSTEK COMPUTER INC., Taipei (TW)

(21) Appl. No.: 12/187,654

(22) Filed: Aug. 7, 2008

(30) Foreign Application Priority Data
Aug. 8, 2007 (TW) 96129282

(51) Int. Cl. H05K 1/02; H05K 1/18

(52) U.S. Cl. 174/255; 174/260

(57) ABSTRACT

A printed circuit board includes a main board part, a reserved board part, a connecting part and a groove. The main board part has a first extending circuit. The reserved board part has a second extending circuit corresponding to the first extending circuit. The connecting part connects the main board part and the reserved board part. The groove is located between the main board part and the reserved board part to prevent the first extending circuit from being electrically connected to the second extending circuit. When the reserved board part needs to be removed, the main board part may be separated from the reserved board part by the groove.

### RELATED APPLICATIONS

This application claims priority to Taiwan Application Serial Number 96129282, filed Aug. 8, 2007, which is herein incorporated by reference.

### BACKGROUND OF THE INVENTION

1. Field of the Invention

The invention relates to a circuit device and, more particularly, to a printed circuit board.

2. Description of the Related Art

With the rapid development of the computer manufacture technology and the electronic industry, the human life is changing a lot. People rely more and more on the smart electronic devices and the electronic devices having automatic control function. With the daily progress of the design and the functions of the electronic circuit and the processor, the modern electronic device provides people easy and close service.

Generally speaking, to couple the control circuit of the electronic product with the electronic element and to obtain the control function, the printed circuit board plays an important role. After the electronic element is installed on the printed circuit board, the printed circuit board is directly or indirectly connected to other controlled electronic equipment or device to obtain the control function.

The printed circuit board applied in the notebook computer often needs to be designed to fit the size of the notebook computer, and then the connector (such as the universal serial bus connector) on the printed circuit board may be exposed from the casing of the notebook computer to allow users to install different peripheral devices easily.

### BRIEF SUMMARY OF THE INVENTION

The invention provides a printed circuit board which is capable of providing at least two appearance sizes to fit different sizes of notebook computers.

A printed circuit board includes a main board part, a reserved board part, a connecting part and a groove. The main board part has a first extending circuit. The reserved board part has a second extending circuit corresponding to the first extending circuit. The connecting part connects the main board part and the reserved board part. The groove is located between the main board part and the reserved board part to prevent the first extending circuit from being electrically connected with the second extending circuit. When the reserved board part needs to be removed, the main board part may be separated from the reserved board part by the groove.

To sum up, the manufacturer providing a printed circuit board with a larger size by providing both the main board part and the reserved board part, thus to cooperate with the notebook computer with a larger size. On the other hand, when the manufacturer wants to use the printed circuit board to cooperate with the notebook computer with a less size, a printed circuit board with a less size is provided by disconnecting the connecting part, removing the reserved board part and remaining the main board part.

These and other features, aspects, and advantages of the present invention will become better understood with regard to the following description, appended claims, and accompanying drawings.

### BRIEF DESCRIPTION OF THE DRAWINGS

FIG. 1 is a top view showing a printed circuit board according to one embodiment of the invention;

FIG. 2 is a three dimensional schematic diagram showing the printed circuit board in FIG. 1 whose reserved board part is removed and to which the connector is installed;

FIG. 3 is a three dimensional schematic diagram showing the printed circuit board in FIG. 1 installed with the resistance and the connector; and

FIG. 4 is a sectional diagram showing the printed circuit board in FIG. 3 along the line segment A-A′.

### DETAILED DESCRIPTION OF THE EMBODIMENTS

Along with the notebook computer becomes more and more diversified, the size of the product emphasizing the performance often is quite different from that of the product emphasizing the appearance. Therefore, conventionally, the manufacturer needs to design special printed circuit board for the notebook computers with different sizes, which is time-consuming and laborious. Along with the product period of the notebook computer becomes short, the constant cost (such as the design expense of the printed circuit board) undertaken by the manufacturer increases.

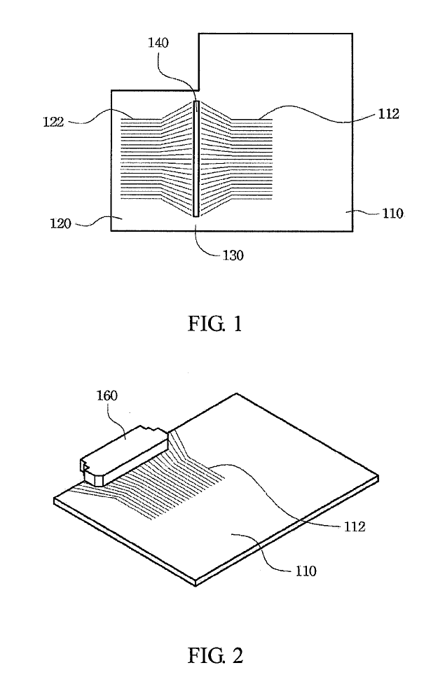

FIG. 1 is a top view showing a printed circuit board according to one embodiment of the invention. As shown in FIG. 1, a printed circuit board includes a main board part 110, a reserved board part 120, a connecting part 130 and a groove 140. The main board part 110 has a first extending circuit 112. The reserved board part 120 has a second extending circuit 122 corresponding to the first extending circuit 112. The connecting part 130 connects the main board part 110 and the reserved board part 120. The groove 140 is located between the main board part 110 and the reserved board part 120 to prevent the first extending circuit 112 from being electrically connected to the second extending circuit 122. When the reserved board part 120 needs to be removed, the main board part 110 may be separated from the reserved board part 120 by the groove 140.

FIG. 2 is a three dimensional schematic diagram showing the printed circuit board whose reserved board part 120 is removed and to which the connector 160 is installed. When the printed circuit board in FIG. 1 is used to cooperate with a notebook computer with a less size, the connecting part 130 may be disconnected first to remove the reserved board part 120 and remain the main board part 110. The connector 160 is connected with the first extending circuit 112 of the main board part 110. Thus, the printed circuit board shown in FIG. 2 is provided to cooperate with the notebook computer with a less size.

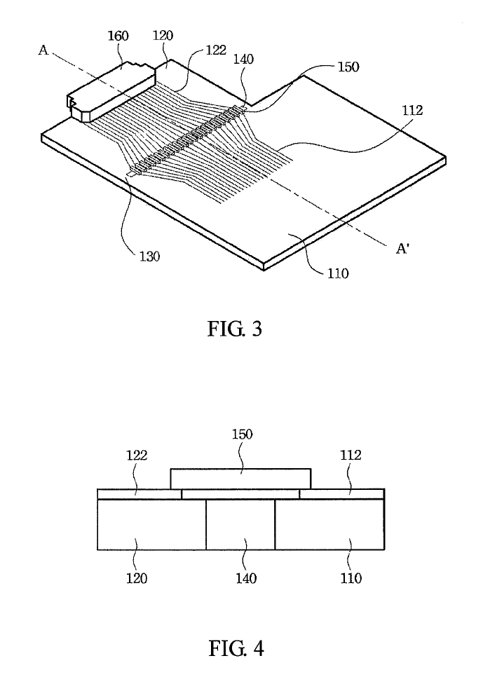

FIG. 3 is a three dimensional schematic diagram showing the printed circuit board in FIG. 1 installed with a resistance 150 and the connector 160. When the printed circuit board in FIG. 1 needs to be used to cooperate with a notebook computer with a larger size, the resistance 150 is used to electrically connect the first extending circuit 112 and the second extending circuit 122. Then, the connector 160 is connected to the second extending circuit 122 of the reserved board part 120. Thus, the printed circuit board shown in FIG. 3 is provided to cooperate with the notebook computer with a larger size.

In detail, since the first extending circuit 112 in FIG. 3 is opposite to and separated from the second extending circuit 122 by the groove 140, the resistance 150 crosses over the groove 140 to electrically connect the first extending circuit 112 and the second extending circuit 122. The first extending circuit 112 may be opposite to the second extending circuit 122 one to one, or not one to one. For example, assuming that the first line of the first extending circuit 112 is a power line, the second and third lines are signal lines, and the fourth line is a grounding line, correspondingly, the first line of the second extending circuit 122 may be a power line, and then the second, third and fourth line are a signal line, a signal line and a grounding line, respectively. Thus, when the resistance 150 crosses over the groove 140, the lines of the first extending circuit 112 is corresponding to that of the second extending circuit 122 one to one. The first line of the second extending circuit 122 also may be a signal line, and then the second, third, fourth line are a power line, a signal line and a grounding line, respectively. Then, when the resistance 150 crosses over the groove 140, the power line of the first extending circuit 112 is connected to the power line of the second extending circuit 122. Furthermore, in the embodiment, the resistance value of the resistance 150 is about zero ohm, which is not limited. As long as the first extending circuit 112 may actually be electrically connected to the second extending circuit 122, the resistance value of the resistance 150 also may be other value.

The word “about” is used to modify any number which may change a little, and the little change dose not change the substance. For example, the resistance value of the resistance 150 is about zero ohm, which not only means the resistance value of the resistance 150 is actually zero ohm, but also means the resistance value of the resistance 150 may be slightly greater than zero ohm as long as the electrical signal may be transmitted from the first extending circuit 112 to the second extending circuit 122.

In addition, the main board part 110, the reserved board part 120 and the connecting part 130 are made of the same material and are located at the same plane. In detail, the main board part 110, the reserved board part 120 and the connecting part 130 are different parts of the same printed circuit board, and the reserved board part 120 is the scrap outside the cutting line when the main board part 110 is cut conventionally. That is, the reserved board part 120 is made by forming the second extending circuit 122 on the scrap which is discarded conventionally, and when the main board part 110 is cut, only the groove 140 is cut between the main board part 110 and the reserved board part 120. The connecting part 130 at the two ends of the groove 140 is reserved and is not completely disconnected. Thus, in the embodiment, the printed circuit board with two different sizes (as shown in FIG. 2 and FIG. 3) is provided via the main board part 110 and the reserved board part 120, and the cost does not increase additionally.

FIG. 4 is a sectional diagram showing the printed circuit board in FIG. 3 along the line segment A-A′, as shown in FIG. 4, the first extending circuit 112 may be apart from the edge of the groove 140. In addition, the second extending circuit 12 also may be apart from the edge of the groove 140. That is, the end points of the first extending circuit 112 and the second extending circuit 122 are away from the edge of the groove 140 in a predetermined distance and are not connected to the edge of the groove 140. When the groove 140 is formed, or the connecting part 130 is disconnected, the ejected conductor chip may pollute the first extending circuit 112 and/or second extending circuit 122 to cause the first extending circuit 112 and/or second extending circuit 122 to be short-circuited. Therefore, parting the first extending circuit 112 and/or the second extending circuit 122 from the edge of the groove 140 may decrease the pollution caused by the conductor chip to the least.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A printed circuit board comprising:
a main board part having a first extending circuit;
a reserved board part having a second extending circuit corresponding to the first extending circuit;
a connecting part connecting the main board part and the reserved board part; and
a groove located between the main board part and the reserved board part to prevent the first extending circuit from being electrically connected to the second extending circuit, when the reserved board part needs to be removed, the main board part is separated from the reserved board part completely by the groove.

2. The printed circuit board according to claim 1, wherein the first extending circuit is opposite to and is separated from the second extending circuit by the groove.

3. The printed circuit board according to claim 1, further comprising a resistance electrically connecting the first extending circuit and the second extending circuit.

4. The printed circuit board according to claim 3, wherein the resistance crosses over the groove.

5. The printed circuit board according to claim 3, wherein the resistance value of the resistance is about zero ohm.

6. The printed circuit board according to claim 3, further comprising a connector connected to the second extending circuit.

7. The printed circuit board according to claim 1, wherein the main board part, the reserved board part and the connecting part are made of the same material.

8. The printed circuit board according to claim 1, wherein the main board part, the reserved board part and the connecting part are located at the same plane.

9. The printed circuit board according to claim 1, wherein the first extending circuit is separated from the edge of the groove.

10. The printed circuit board according to claim 1, wherein the second extending circuit is separated from the edge of the groove.
